(19) United States
(12) Patent Application Publication
(10) Pub. No.: US 2011/0069556 A1
(43) Pub. Date: Mar. 24, 2011

(54) NAND FLASH MEMORY

(75) Inventors: Tomoki HIGASHI, Yokohama-Shi (JP); Kazumi Tanimoto, Kamakura-Shi (JP)

(73) Assignee: Kabushiki Kaisha Toshiba, Tokyo (JP)

(21) Appl. No.: 12/862,097

(22) Filed: Aug. 24, 2010

(30) Foreign Application Priority Data
Sep. 24, 2009 (JP) 2009-218994

(51) Int. Cl. G11C 16/06

(52) U.S. Cl. 365/185.22; 365/185.24

(57) ABSTRACT

A NAND flash memory has a memory cell transistor, the memory cell transistor including a charge storage layer formed over a well of a semiconductor substrate surface via a first insulation film and insulated from surroundings, and a control gate provided over the charge storage layer via a second insulation film, the memory cell transistor storing information according to a threshold voltage which depends on a charge quantity retained by the charge storage layer; and a control circuit which controls operation of the memory cell transistor by controlling a voltage applied to the control gate and a voltage applied to the well.

### CROSS-REFERENCE TO RELATED APPLICATION

This application is based upon and claims the benefit of priority from the prior Japanese Patent Application No. 2009-218994, filed on Sep. 24, 2009, the entire contents of which are incorporated herein by reference.

### BACKGROUND

1. Field

Embodiments described herein relate generally to a NAND flash memory in which information writing/erasing is conducted by applying a high electric field to inject/remove charges into/from a floating gate or a charge storage layer.

2. Background Art

In the conventional nonvolatile semiconductor memories, there are, for example, the floating-gate type, the SONOS (Silicon-Oxide-Nitride-Oxide-Silicon) type, and the MONOS (Metal-Oxide-Nitride-Oxide-Silicon) type.

These non-volatile semiconductor memories store information (data) by retaining charges (electrons or holes) in a floating gate or a charge storage layer which is isolated from the surroundings by an insulation film such as SiO₂. Since the threshold voltage Vt of memory cell transistors varies according to the quantity of retained charge, information (data) is determined by sensing it.

Information writing/erasing, i.e., charge injection/removal is conducted by a tunnel current, which is caused by a high electric field from a Si substrate or a control gate, or hot carriers from the Si substrate (see, for example, JP-A2003-173690 (KOKAI)).

No matter which of the injection methods is used, repetition of the information writing/erasing causes charge to pass through the inside of an insulation film such as SiO₂ repetitively. When passing through the insulation film, the charge damages the insulation film and generates a large number of electron traps and hole traps.

Then, the generated traps bring about various problems.

### BRIEF DESCRIPTION OF THE DRAWINGS

FIG. 1 is a schematic diagram showing band structures near the tunnel oxide film in a state in which a write pulse is applied to the control gate;

FIG. 2 is a schematic diagram showing band structures near the tunnel oxide film at the time of verify read;

FIG. 3 is a schematic diagram showing band structures near the tunnel oxide film at the time of ordinary read;

FIG. 4 is a diagram showing distribution of the threshold voltage involving the verify noise and the like;

FIG. 5 is a block diagram showing a configuration of a principal part of a NAND flash memory 100 according to a first embodiment;

FIG. 6 is a circuit diagram showing an example of a circuit configuration of the memory cell array 1 shown in FIG. 5;

FIG. 7 is a sectional view showing an element structure of NAND cell units in the column direction of the memory cell array 1 shown in FIG. 6;

FIG. 8 is a diagram showing distribution of threshold voltage of the memory cell transistor M in the case where eight-value (3-bit) data is stored;

FIG. 9 is a diagram showing an example of configurations of the sense amplifier circuit 3 and the data register circuit 12 shown in FIG. 5;

FIG. 10 is a flow chart showing an example of write operation of the NAND flash memory 100 according to the first embodiment;

FIG. 11 is a diagram showing an example of relations among the threshold voltage, the verify level and the number of cells of the memory cell transistors M in the NAND flash memory cell according to the first embodiment;

FIG. 12 is a diagram showing another example of configurations of the sense amplifier circuit 3 and the data register circuit 12;

FIG. 13 is a flow chart showing an example of write operation of data of low order (a first bit) of the NAND flash memory 100 according to the second embodiment;

FIG. 14 is a flow chart showing an example of write operation of data of high order (a second bit) of the NAND flash memory 100 according to the second embodiment;

FIG. 15 is a diagram showing an example of relations among the threshold voltage, the verify level and the number of cells of the memory cell transistors M in the NAND flash memory cell according to the second embodiment; and

FIG. 16 is a flow chart showing another example of write operation of data of high order (a second bit) of the NAND flash memory 100 according to the second embodiment.

### DETAILED DESCRIPTION

If the already-described size shrinking of the memory cell transistor proceeds, variation of the threshold voltage caused by unit charge (elementary charge e) becomes great. For example, in the flash memory of floating gate type in the 20-nm generation, the threshold voltage changes by approximately 5 to 20 mV if the number of electrons in the floating gate changes by one.

If the threshold voltage change caused by unit charge becomes great, then the influence of two kinds of random telegraph noise, i.e., program noise and read noise becomes no considerable.

The program noise is noise caused by statistical fluctuation in the number of electrons which are injected into the floating gate or the charge storage layer by one program (write) pulse.

If, for example, the threshold voltage is raised by 0.2 V for one write pulse, then ten to several tens electrons on an average are injected by one write pulse in the 20 to 30 nm generation. The number of electrons injected by one write pulse follows the Poisson distribution. If the average number of injected electrons becomes small, therefore, the variance becomes great. In other words, the number of injected electrons distributes widely around the average number of injected electrons. The threshold voltage change caused by one write pulse also distributes widely around 0.2 V.

When conducting write operation by using stepup writing involving verify operation, the influence of the program noise appears as spread of the upper skirt in the threshold voltage distribution. As the size shrinking of the memory cell transistor advances, the number of injected electrons required to cause the same threshold voltage change decreases and consequently the program noise becomes great.

The read noise is caused by electrons or holes randomly getting into or coming out from electron traps or hole traps which exist near the silicon substrate interface in the tunnel oxide film of the memory cell transistor.

The threshold change caused depending on whether an electron or a hole is trapped in one electron trap or hole trap changes according to a place where the trap exists (position in the channel area and depth of tunnel oxide film). In general, it is represented by expression (1). In expression (1), q is elementary charge, Cox is gate capacitance per unit area, W is channel width, L is channel length.

ΔVth≈q/(Cox*W*L) (1)

Since the NAND flash memory uses a thick tunnel oxide film in order to ensure data retention characteristics, Cox is small and the threshold voltage change is great.

According to recent studies, it is found that a threshold voltage change which is far greater than expected according to Expression (1) occurs considering percolation of the current path caused by impurity atoms doped to the silicon substrate. In addition, it is also found that dependence of scaling is not inverse proportion to W*L in Expression (1), but is inverse proportion to √(W*L). As a matter of fact, a threshold voltage change which exceeds 100 mV is observed in the NAND flash memory of the 50 nm generation.

The threshold voltage changes according to whether the trap has captured charge when conducting read operation. Therefore, the influence of the read noise appears as spread of both skirts (upper skirt and lower skirt) of the threshold voltage distribution. Since the change of the threshold voltage increases in inverse proportion to √(W*L) or (W*L), the noise becomes great as the size shrinking of the memory cell transistor is promoted. It is expected that noise exceeding 300 mV will occur from the 30 nm generation on, especially in the 20 nm generation.

The verify noise is caused by the electron traps or hole traps which exist in the tunnel oxide film of the memory cell transistor in the same way as the read noise. The verify noise is caused because the number of charges captured in the electron traps or hole traps when conducting verify read immediately after application of a write pulse differs from that when conducting read operation after elapse of time.

The verify noise will be described in more detail by taking a NAND flash memory of floating gate type as an example.

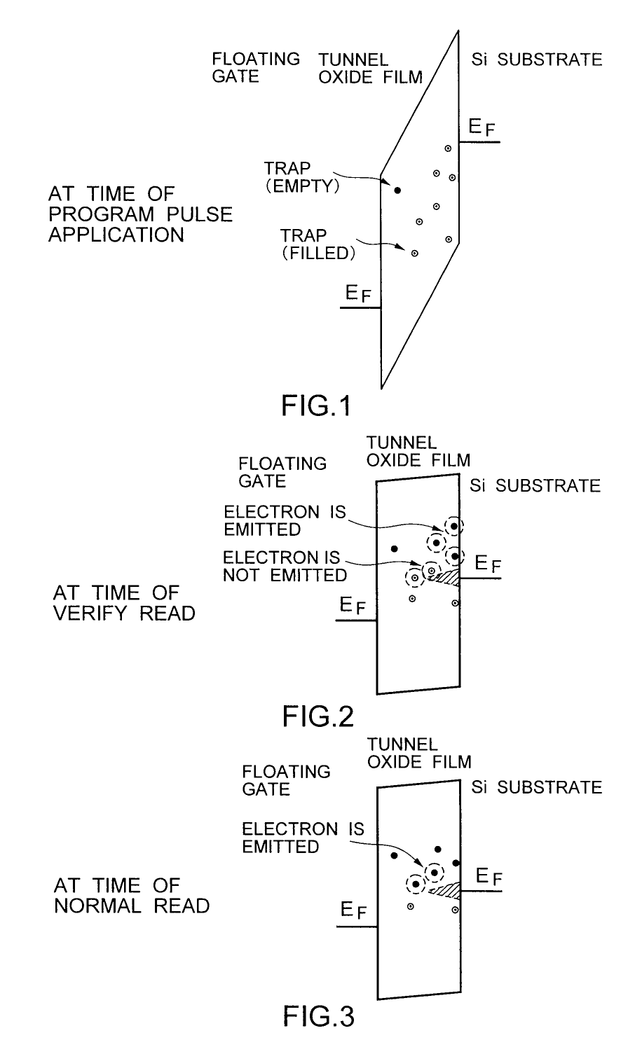

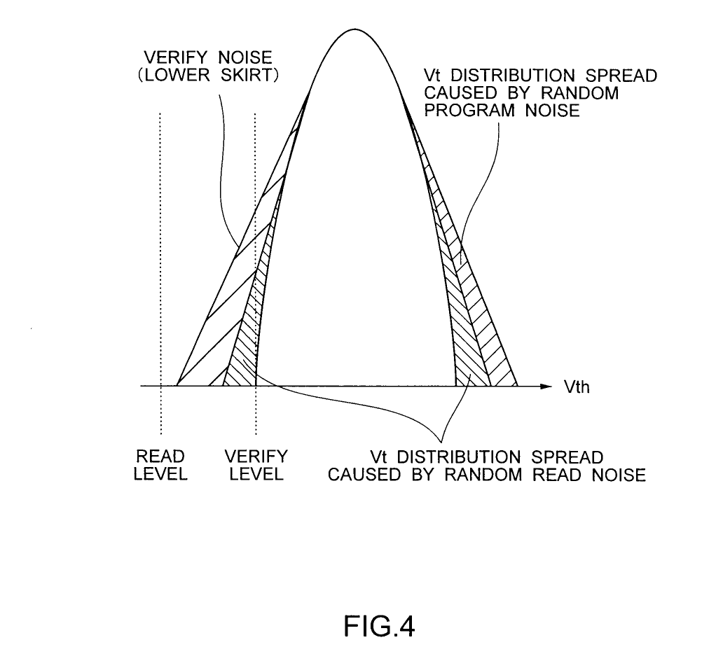

FIG. 1 is a schematic diagram showing band structures near the tunnel oxide film in a state in which a write pulse is applied to the control gate. FIG. 2 is a schematic diagram showing band structures near the tunnel oxide film at the time of verify read. FIG. 3 is a schematic diagram showing band structures near the tunnel oxide film at the time of ordinary read. FIG. 4 is a diagram showing distribution of the threshold voltage involving the verify noise and the like.

For example, if a high voltage (10 to 20 V) is applied to the control gate at the time of write operation, a high electric field is generated in the tunnel oxide film between the floating gate and the silicon substrate. As a result, an FN (Fowler-Nordheim) current flows and electrons are injected to the floating gate. At that time, a large number of electron traps in the tunnel oxide film are located below the Fermi level E_{F} of the silicon substrate, and most of them capture electrons (FIG. 1).

If the gate voltage is restored to a voltage in the range of 0 V to nearly power supply voltage after application of the write pulse, the Fermi level E_{F} of the silicon substrate falls and electron traps which have captured electrons begin to emit electrons simultaneously.

During a period in the range of several μs to several tens μs until the verify read is conducted, however, all electron traps having a Fermi level of E_{F} or above of the silicon substrate cannot emit electrons. Therefore, the verify read operation is conducted without emitting partial electrons (FIG. 2).

In the state in which electron traps in the tunnel oxide film remain to capture electrons, the threshold voltage of the memory cell transistor becomes high due to the same cause as that of the read noise. It is possible that the threshold voltage is determined to have arrived at the preset level (verify level) in the high threshold voltage state and the writing is finished. In this case, the threshold voltage of the memory cell transistor becomes lower than the preset level after the electron traps emit electrons with elapse of time (FIG. 3).

At the time of actual read operation, therefore, the low threshold voltage state is read. After the writing is finished, therefore, memory cell transistors having a threshold voltage which is lower than the preset level are generated. In other words, the threshold voltage distribution spreads on the lower skirt side of the threshold distribution (FIG. 4).

The change of the threshold voltage caused by one electron or hole captured in a trap has been described with reference to the read noise. If the size of the memory cell transistor is shrunk, the change becomes great. Therefore, the verify noise also becomes great as the size of the memory cell transistor is shrunk. It is expected that great noise is generated especially from the 30 nm generation on (the minimum line width of the memory cell transistor M is 30 nm or less).

In order to solve the above-described problem, an object of the present invention is to provide a NAND flash memory capable of suppressing expansion of the distribution width of the threshold voltage of the memory cell transistor.

A NAND flash memory according to the present invention includes a memory cell transistor, the memory cell transistor including a charge storage layer formed over a well of a semiconductor substrate surface via a first insulation film and insulated from surroundings, and a control gate provided over the charge storage layer via a second insulation film, the memory cell transistor storing information according to a threshold voltage which depends on a charge quantity retained by the charge storage layer; and a control circuit which controls operation of the memory cell transistor by controlling a voltage applied to the control gate and a voltage applied to the well.

The control circuit injecting charges into the charge storage layer by applying a first program voltage between the control gate and the well in a first program operation. The control circuit making a determination whether the threshold voltage of the memory cell transistor exceeds a first verify level in a first verify operation after the first program operation. Upon determining the threshold voltage of the memory cell transistor to exceed the first verify level in the first verify operation, the control circuit making a determination whether the threshold voltage of the memory cell transistor exceeds a second verify level which is lower than the first verify level in a second verify operation after the first verify operation. Upon determining the threshold voltage of the memory cell transistor not to exceed the second verify level in the second verify operation, the control circuit injecting charges into the charge storage layer by applying a second program voltage which is lower than the first program voltage between the control gate and the well in a second program operation after the second verify operation.

Hereafter, embodiments according to the present invention will be described with reference to the drawings. Ensuing embodiments will be described by taking a NAND flash memory of floating gate type as an example. However, the embodiments are applied to the NAND flash memory of SONOS type (or MONOS type) as well in the same way.

### First Embodiment

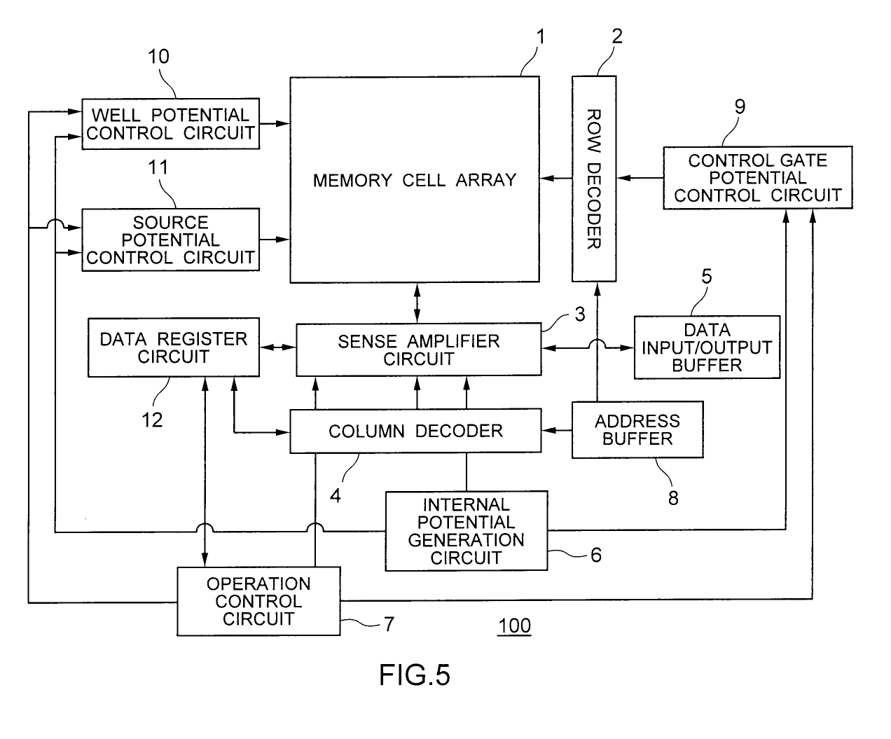

FIG. 5 is a block diagram showing a configuration of a principal part of a NAND flash memory 100 according to a first embodiment.

As shown in FIG. 5, the NAND flash memory 100 includes a memory cell array 1, a row decoder 2, a sense amplifier circuit 3, a column decoder 4, a data input/output buffer 5, an internal potential generation circuit 6, an operation control circuit 7, an address buffer 8, a control gate potential control circuit 9, a well potential control circuit 10, a source potential control circuit 11, and a data register circuit 12.

The memory cell array 1 includes a plurality of NAND strings arranged in a matrix form and connected to word lines WL in the row direction and bit lines BL in the column direction as described below.

The row decoder 2 includes a word line drive circuit (not illustrated), and conducts word line selection and drive of the memory cell array 1.

The sense amplifier circuit 3 includes a circuit (not illustrated) which controls a potential on a bit line BL and a sense amplifier (not illustrated) which senses a voltage on a bit line at the time of read operation. The sense amplifier circuit 3 conducts write control, verify read, or read operation by controlling the potential on the bit line BL. The NAND flash memory conducts write operation and read operation by taking, for example, a page in the range of 512 bytes to 8 Kbytes as the unit. In other words, the sense amplifier 3 can perform control of bit lines BL corresponding to 512 bytes to 8 Kbytes in the page simultaneously.

The column decoder 4 conducts selection of a sense amplifier circuit 3 connected to bit lines of the memory cell array 1.

At the time of data reading, data read out onto the sense amplifier circuit 3 is output to an input/output control circuit (not illustrated) via the data input/output buffer 5.

The internal potential generation circuit 6 raises or lowers the power supply voltage and generates a voltage to be supplied to the sense amplifier circuit 3, the control gate potential control circuit 9, the well potential control circuit 10 and the source potential control circuit 11.

The control gate potential control circuit 9 controls a voltage to be applied to a control gate CG of a memory cell transistor M, and supplies the voltage to the row decoder 2.

An address of the memory cell transistor M supplied from the input/output control circuit (not illustrated) is transferred to the row decoder 2 and the column decoder 4 via the address buffer 8.

The well potential control circuit 10 controls a potential on a cell well 102 of a semiconductor substrate 101.

The source potential control circuit 11 controls a potential on a source line SRC.

If an external control signal such as a chip enable signal CE, a write enable signal WE, a read enable signal RE, an address latch enable signal ALE, or a command latch enable signal CLE is input from the outside of the chip to an input pin (not illustrated) and a command code is input to an input/output data pin (not illustrated), then a command code is supplied to a command buffer (not illustrated) via the input/output control circuit (not illustrated). The command buffer decodes the command code and supplies a result to the operation control circuit 7 as a command signal.

The operation control circuit 7 performs sequence control of data writing and erasing and data reading control based on a command signal supplied according to the operation mode.

The operation control circuit 7 outputs signals for controlling various operations such as reading, writing and erasing. As a result, the sense amplifier circuit 3, the internal potential generation circuit 6, the control gate potential control circuit 9, the well potential control circuit 10, and the source potential control circuit 11 generate potentials for various operations. The operation control circuit 7 is adapted to conduct the verify operation.

The data register circuit 12 is adapted to store data which has been read out or write data.

The operation control circuit 7 makes a determination whether the threshold voltages of all memory cell transistors M in a writing object page or an erasing object block have reached the verify level (whether written or erased) for a predetermined memory cell transistor M based on a result sensed by the sense amplifier circuit 3 at the time of verify read (data stored in the data register circuit 12).

For example, a relation indicating whether the threshold voltage of a memory cell transistor M connected to the selected word line WL is greater than a verify voltage Vvfy is sensed by the sense amplifier circuit 3, and data depending on the sensing result is stored in the data register circuit 12. Then, the operation control circuit 7 makes a determination whether threshold voltages of all writing object memory cells on a page or all memory cells while leaving the preset allowable number of bits or preset allowable number of bytes have reached the verify level (have been written), i.e., whether the write verify has been passed.

The operation control circuit 7 controls the sense amplifier circuit 3, the control gate potential control circuit 9, the well potential control circuit 10 and the source potential control circuit 11 based on the result of verification, and continues write operation or erase operation until the threshold voltages of all memory cell transistors M in a writing object page or the threshold voltages of all memory cell transistors M in an erasing object block have reached the verify level (have passed).

Some of the operation control circuits 7 have a function of counting the number of memory cell transistors M (the number of bits) which have not reached the verify level or counting the number of bit lines or columns coupled to memory cell transistors M which have not reached the verify level. In that case, if the number of memory cell transistors M which have not reached the verify level or the number of bit lines or columns coupled to memory cell transistors which have not reached the verify level is within the preset allowable number of bits or the preset allowable number of bytes, it is possible to discontinue the write or erase operation at that time point.

The state in which the number of bits or the number of columns which have not reached the verify level is within the allowable number of bits or the allowable number of bytes is referred to as pseudo passed, whereas the state in which the all bits or columns have reached the verify level is referred to as passed.

In the NAND flash memory, it is conducted to correct defective bits generated over several to several tens bits by various disturbances or data retention characteristic defects by using the ECC technique. When there is a sufficient number of correctable bits, however, there is no problem even if the write operation or erase operation is disconnected by a pseudo pass and the state in which partial memory cell transistors M do not reach the verify level is left as it is. By doing so, it is avoided to repeat the write or erase operation because of memory cell transistors M which are slow in writing or erasing and consequently the write performance or the erase performance can be improved.

As described heretofore, the control circuits 3, 7, 9, 10 and 11 shown in FIG. 5 are adapted to control voltages applied to the control gate CGs (word lines), cell wells, source lines and bit lines and control operations of the memory cell transistors M.

A configuration of a NAND string formed by connecting memory cells M in series will now be described in more detail.

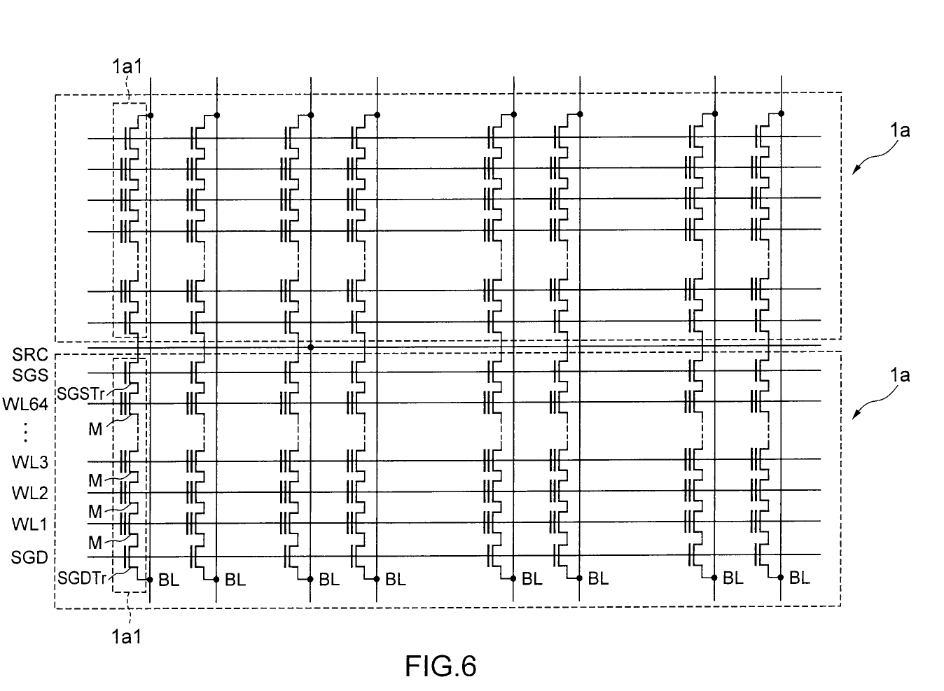

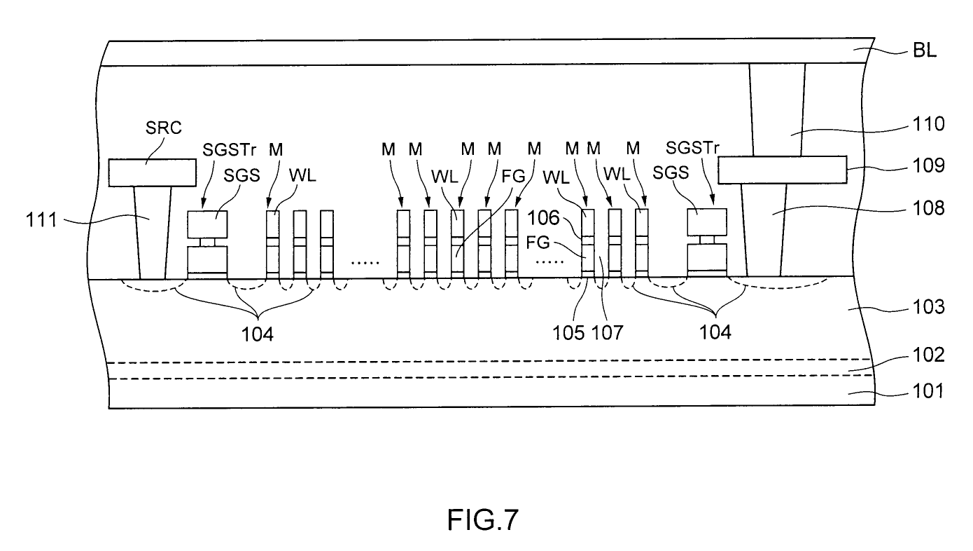

FIG. 6 is a circuit diagram showing an example of a circuit configuration of the memory cell array 1 shown in FIG. 5. FIG. 7 is a sectional view showing an element structure of NAND cell units in the column direction of the memory cell array 1 shown in FIG. 6.

As shown in FIG. 6, the memory cell array 1 includes a block 1a formed by connecting a plurality of NAND cell units 1a1 as already described.

Each NAND cell unit 1a1 includes, for example, 64 memory cell transistors M, a selection gate transistor SGDTr, and a selection gate transistor SGSTr connected in series.

The first selection gate transistor SGDTr is connected to a bit line BL. The second selection gate transistor SGSTr is connected to a source line SRC.

Control gates of memory cell transistors M arranged on each row are connected to each word line WL.

Gates of the first selection gate transistors SGDTr are connected to a select line SGD. Gates of the second selection gate transistors SGSTr are connected to a select line SGS.

As shown in FIG. 7, a cell well 103, which is a p-type semiconductor, surrounded by a well 102, which is an n-type semiconductor, is formed on a p-type semiconductor substrate 101. Diffusion layers 104, which are n-type semiconductors, are formed in the cell well 103.

Each memory cell transistor M is formed of its source and drain formed of the diffusion layers 104, a floating gate FG which is a charge storage layer provided over a channel region between the source and the drain via a tunnel insulation film 105, and a control gate CG which is a word line WL provided over the floating gate FG via an insulation film 106. As for the insulation film 106, a film having a high dielectric constant is desirable. In general, a film having a laminate structure of a Si oxide film and a Si nitride film is frequently used.

The floating gate FG is isolated from the surroundings by the tunnel insulation film 105, the insulation film 106 and an interlayer film 107. If the NAND flash memory is the SONOS type (or the MONOS type), then the charge storage layer is not the floating gate FG, but a charge storage layer formed of a Si nitride film or the like is used.

The memory cell transistor M can store different bit information according to a threshold voltage depending on a charge quantity retained in the floating gate FG.

The threshold voltage depends on the quantity of charge stored in the floating gate FG. The quantity of charge stored in the floating gate FG can be changed by a tunnel current which flows through the tunnel insulation film 105.

In other words, if the control gate CG (word line WL) is provided with a voltage which is sufficiently high than that of the cell well 103 and the diffusion layer (source-drain region) 104, then electrons are injected into the floating gate FG through the tunnel insulation film 105. As a result, the threshold voltage of the memory cell transistor M becomes high.

On the other hand, if the cell well 103 and the diffusion layer (source-drain region) 104 are provided with a voltage which is sufficiently higher than that of the control gate CG (word line WL), then electrons are emitted from the floating gate FG through the tunnel insulation film 105. As a result, the threshold voltage of the memory cell transistor M becomes low.

In this way, data stored in the memory cell transistor M can be rewritten by controlling the quantity of charge stored in the floating gate FG.

As shown in FIG. 7, the selection gate transistor SGDTr and the selection gate transistor SGSTr are also formed in the cell well 103.

The selection gate transistor SGDTr is formed of its source and drain formed of diffusion layers 104, and a selection gate line SGD having a structure of two layers connected electrically. The drain of the selection gate transistor SGDTr is connected to a bit line BL via a contact electrode 108, a metal interconnection layer 109 and an inter-interconnection electrode 110. The selection gate transistor SGDTr is controlled by a voltage applied from the row decoder 2 to the selection gate line SGD.

The selection gate transistor SGSTr is formed of its source and drain formed of diffusion layers 104, and a selection gate line SGS having a structure of two layers connected electrically. The source of the selection gate transistor SGSTr is connected to a source line SRC via a contact electrode 111. The selection gate transistor SGSTr is controlled by a voltage applied from the row decoder 2 to the selection gate line SGS.

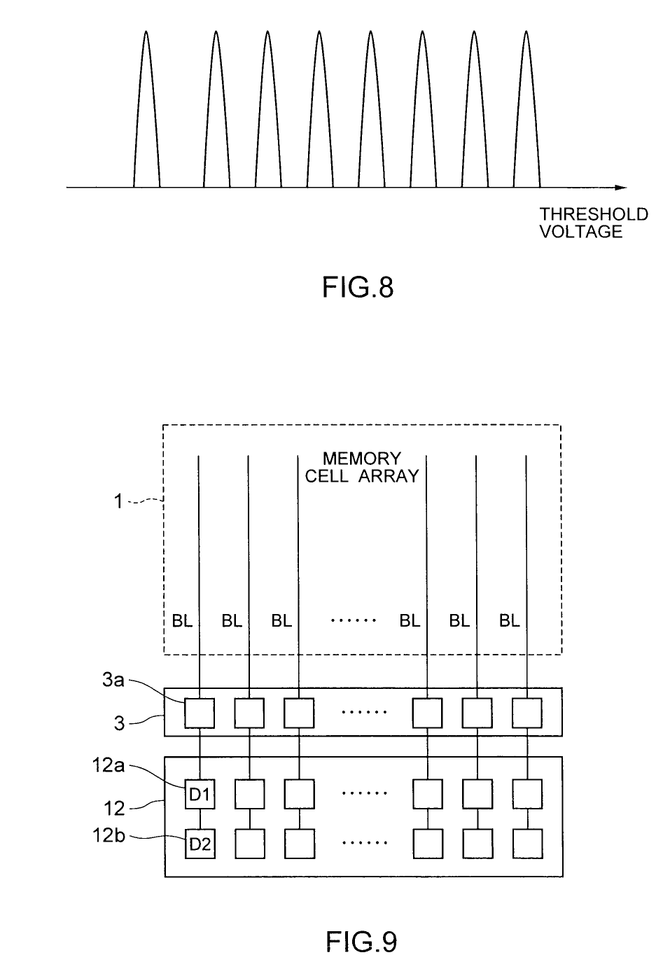

FIG. 8 is a diagram showing distribution of threshold voltage of the memory cell transistor M in the case where eight-value (3-bit) data is stored. For example, if the threshold voltage is controlled into eight states, 3-bit information can be stored in one memory cell transistor M. The bit information stored in the memory cell transistor M can be read out by applying a selection read voltage to a selected word line WL (control gate CG) and applying an unselected read voltage to unselected word lines (control gates CG).

FIG. 9 is a diagram showing an example of configurations of the sense amplifier circuit 3 and the data register circuit 12 shown in FIG. 5.

As shown in FIG. 9, the sense amplifier circuit 3 includes sense amplifiers 3a respectively connected to a plurality of bit lines BL in the memory cell array 1.

The data register circuit 12 includes a plurality of registers 12a and a plurality of registers 12b. Each pair of registers 12a and 12b is disposed to be connected to one sense amplifier 3a (i.e., one bit line B1).

Each of the registers 12a and 12b is adapted to store data according to a result obtained by sensing a potential on the bit line BL with the sense amplifier 3a (i.e., a result corresponding to the threshold voltage of the memory cell transistor M).

Write operation of the NAND flash memory 100 according to the second embodiment having the configuration described heretofore will now be described.

In the NAND flash memory according to the present second embodiment, the stepup write scheme is used. In the stepup write scheme, write pulse application and the verify read are repeated while raising a program voltage Vpgm little by little until a memory cell transistor of writing object is written to a desired verify level or above.

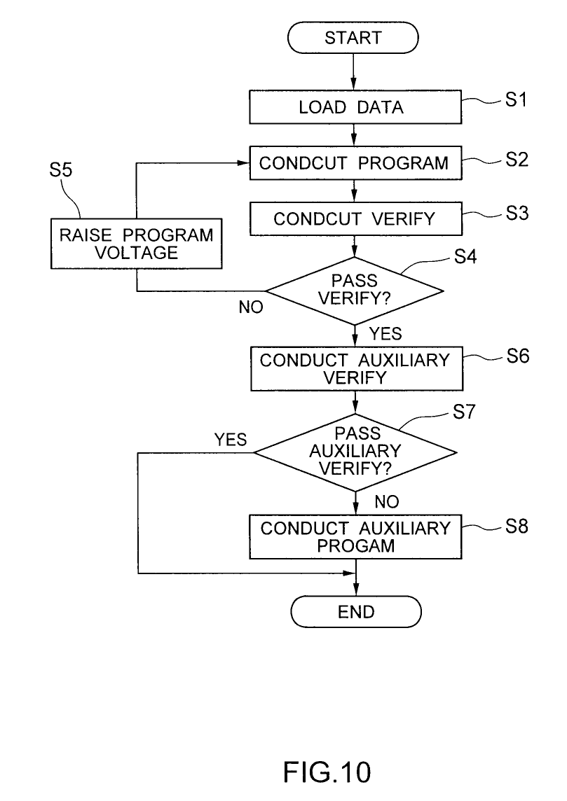

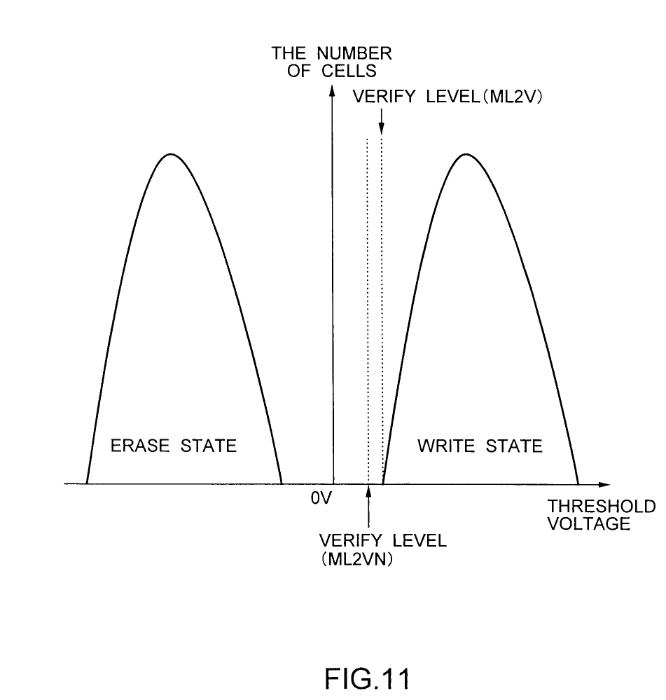

FIG. 10 is a flow chart showing an example of write operation of the NAND flash memory 100 according to the first embodiment. FIG. 11 is a diagram showing an example of relations among the threshold voltage, the verify level and the number of cells of the memory cell transistors M in the NAND flash memory cell according to the first embodiment.

As shown in FIG. 10, the operation control circuit 7 first loads data. In other words, the same write data is stored in the registers 12a and 12b in the data register circuit 12 (step S1). If write data loaded in the data register circuit 12 is data corresponding to the erase state (writing is not necessary), writing into the pertinent memory cell transistor M is not conducted.

Then, the operation control circuit 7 applies a first program voltage Vpgm1 between a control gate of a selected memory cell transistor M on a writing object page and the well by using a first program operation. As a result, charge is injected into a charge storage layer of the memory cell transistor M (step S2). Incidentally, the potential is controlled to prevent charge from being injected into memory cell transistors M which have already passed the verify described below.

Then, the operation control circuit 7 reads data stored in the memory cell transistor M by first verify operation (ordinary verify operation) after the first program operation (step S3). As a result, verify data sensed by the sense amplifier circuit 3 is overwritten in the register 12a. For example, if the threshold voltage of the memory cell transistor M exceeds a verify level ML2V (FIG. 11) (writing is completed), data stored in the register 12a changes, for example, from “0” to “1.”

The operation control circuit 7 makes a determination whether the threshold voltage of the memory cell transistor M has exceeded the first verify level ML2V (FIG. 11) based on data stored in the data register circuit 12 by the first verify operation (step S4).

If the operation control circuit 7 determines at the step S4 that the threshold voltage of the memory cell transistor M has not exceeded the first verify level ML2V in the first verify operation, then the processing proceeds to step S5. At the step S5, the first program voltage Vpgm1 is raised, and the processing returns to the step S2 to conduct the first program operation again. Thereafter, the already described operation is conducted.

On the other hand, if the operation control circuit 7 determines at the step S4 that the threshold voltage of the memory cell transistor M has exceeded the first verify level ML2V in the first verify operation, then the operation control circuit 7 recognizes that the threshold voltage of the memory cell transistor M has passed the first verify and conducts second verify operation (auxiliary verify) after the first verify operation (step S6).

The operation control circuit 7 makes a determination whether the threshold voltage of the memory cell transistor M has exceeded a second verify level ML2VN (FIG. 11) which is lower than (for example, 0.1 V lower than) the first verify level ML2V (step S7).

If the operation control circuit 7 determines at the step S7 that the threshold voltage of the memory cell transistor M has not exceeded the second verify level ML2VN in the second verify operation (auxiliary verify operation), then the processing proceeds to step S8. At the step S8, a second program voltage Vpgm2 which is lower than (for example, 2 V lower than) the first program voltage Vpgm1 is applied between the control gate of the memory cell transistor M and the well by using a second program operation (auxiliary program operation) after the second verify operation. As a result, charge is injected into a charge storage layer of the memory cell transistor M.

As a result, write operation on the memory cell transistor M of the pertinent page is finished.

In the second program operation, the operation control circuit 7 controls, for example, the voltage applied to the control gate of the memory cell transistor M to cause the second program voltage Vpgm2 to become lower than the first program voltage Vpgm1.

Or the operation control circuit 7 may control a voltage on the well (a voltage on the channel between diffusion layers of the memory cell transistor M) in the second program operation to cause the second program voltage Vpgm2 to become lower than the first program voltage Vpgm1. In this case, for example, the operation control circuit 7 controls the voltage on the well by raising the potential on a bit line connected electrically to the diffusion layer of the memory cell transistor M.

On the other hand, if the operation control circuit 7 determines at the step S7 that the threshold voltage of the memory cell transistor M has exceeded the second verify level ML2VN in the second verify operation (auxiliary verify operation), then the operation control circuit 7 recognizes that the threshold voltage of the memory cell transistor M has passed the second verify (auxiliary verify) and the second program operation is not conducted.

As a result, write operation on the memory cell transistor M on the pertinent page is finished.

In the conventional art, the threshold voltage of the memory cell transistor M reads higher because of the random telegraph noise, and writing is finished before the original writing completion as already described.

In the present first embodiment, however, the auxiliary verify is conducted and in addition the auxiliary program operation is conducted. As a result, it is possible to write desired data (raise the threshold voltage to a level exceeding the desired verify level ML2V) on the memory cell transistor M influenced by the random telegraph noise (FIG. 11).

Consequently in the NAND flash memory 100, it becomes possible to suppress the spread of the distribution width of the threshold voltage after the writing. Especially from the 30-nm generation (having the minimum line width of the memory cell transistor M of 30 nm or less) on which occurrence of great noise is expected, the spread of the distribution width of the threshold voltage after the writing can be suppressed more effectively.

As already described, the verify level ML2VN of the second verify (auxiliary verify) is set to be lower than the verify level of the first verify. As a result, it is possible to prevent the threshold voltage of the memory cell transistor M from becoming higher than needed (i.e., prevent the distribution width of the threshold voltage from expanding than needed) owing to the auxiliary program according to the auxiliary verify.

In the NAND flash memory according to the present embodiment, the spread of the distribution width of the threshold voltage of the memory cell caused by the verify noise can be suppressed as heretofore described.

### Second Embodiment

In the first embodiment, the case where data stored in the memory cell transistor is a binary value (1 bit) has been described.

In embodiments according to the present invention, application to the case where data assumes a multiple value is also possible.

In the present second embodiment, therefore, the case where data stored in the memory cell transistor assumes a multiple value (especially four values (2 bits)) will be described.

In the same way as the first embodiment, a method described in the second embodiment is executed by, for example, the NAND flash memory 100 shown in FIG. 5. Read operation of the NAND flash memory 100 is the same as that in the first embodiment.

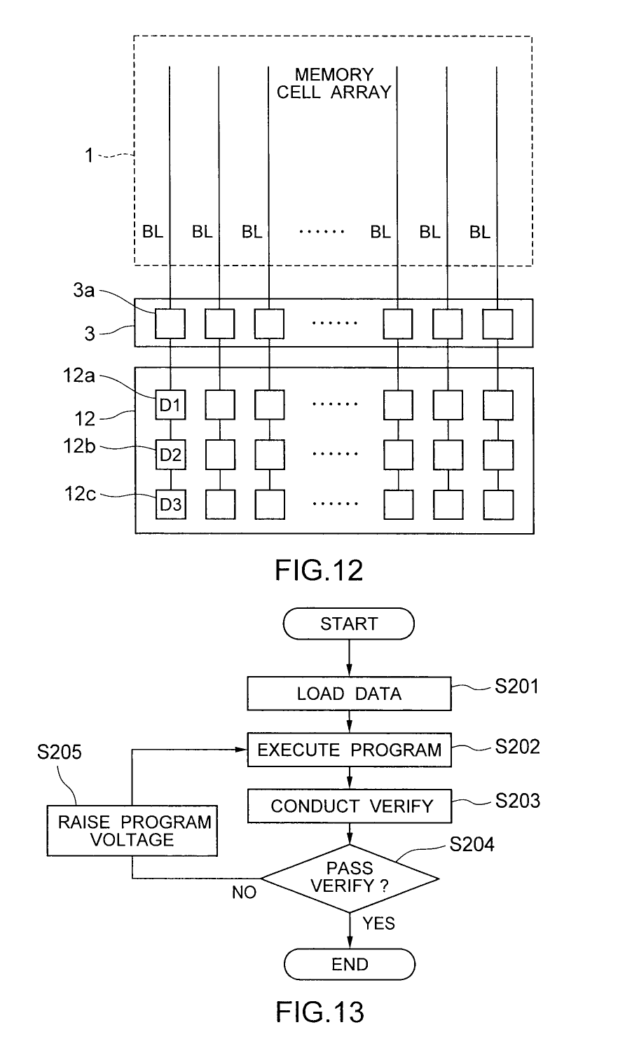

The second embodiment differs in the configuration of the data register circuit 12 from the first embodiment. FIG. 12 is a diagram showing another example of configurations of the sense amplifier circuit 3 and the data register circuit 12.

As shown in FIG. 12, the sense amplifier circuit 3 includes sense amplifiers 3a respectively connected to a plurality of bit lines BL in the memory cell array 1.

The data register circuit 12 includes a plurality of registers 12a, a plurality of registers 12b, and a plurality of registers 12c. Each set of registers 12a, 12b and 12c is disposed to be connected to one sense amplifier 3a (i.e., one bit line B1).

Each of the registers 12a, 12b and 12c is adapted to store data according to a result obtained by sensing a potential on the bit line BL with the sense amplifier 3a (i.e., a result corresponding to the threshold voltage of the memory cell transistor M).

The second embodiment is the same as the first embodiment in other configurations.

Write operation of the NAND flash memory 100 having the configuration described heretofore will now be described.

In the NAND flash memory according to the present first embodiment, the stepup write scheme already described is used.

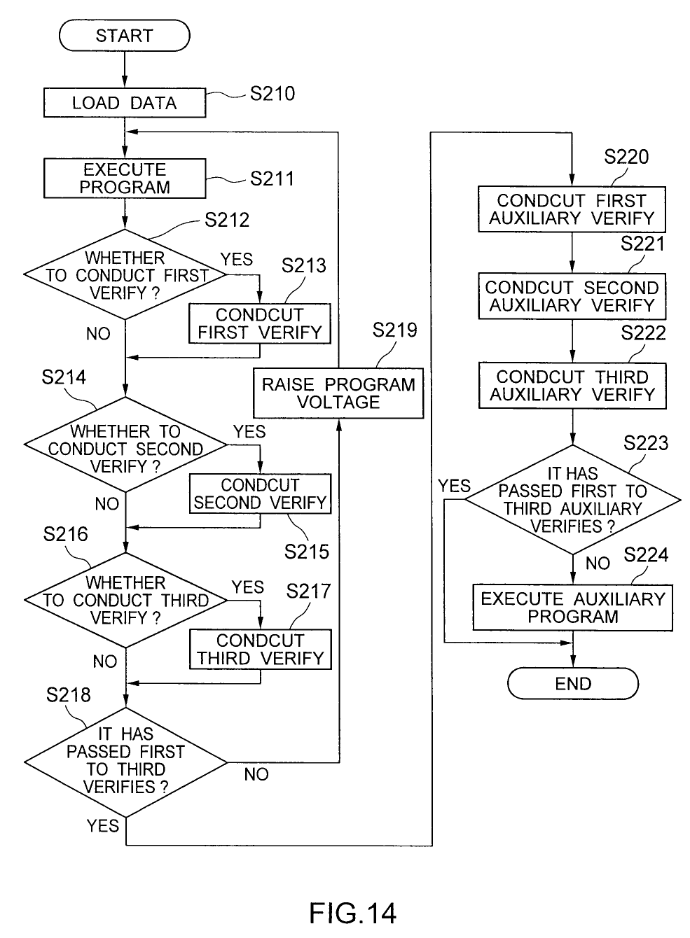

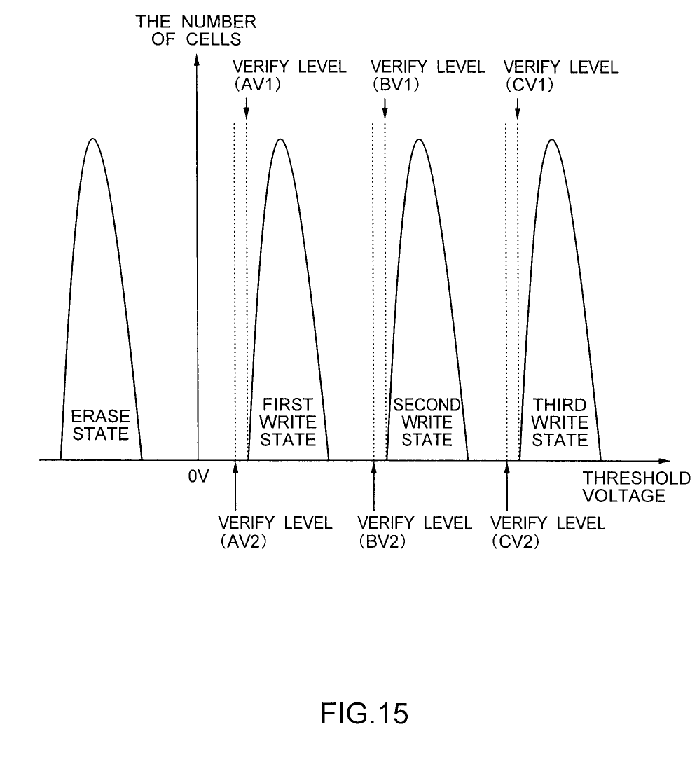

FIG. 13 is a flow chart showing an example of write operation of data of low order (a first bit) of the NAND flash memory 100 according to the second embodiment. FIG. 14 is a flow chart showing an example of write operation of data of high order (a second bit) of the NAND flash memory 100 according to the second embodiment. FIG. 15 is a diagram showing an example of relations among the threshold voltage, the verify level and the number of cells of the memory cell transistors M in the NAND flash memory cell according to the second embodiment.

In the write operation of the data of the low order (the first bit), the already described auxiliary verify is not conducted. In the write operation of the data of the high order (the second bit) in which the final threshold voltage is fixed, the already described auxiliary verify is conducted.

As shown in FIG. 13, the operation control circuit 7 first loads data. In other words, the operation control circuit 7 causes write data to be stored in the register 12a in the data register circuit 12 (step S201). If write data loaded in the data register circuit 12 is data corresponding to the erase state (writing is not necessary), write operation is not conducted.

Then, the operation control circuit 7 applies a program voltage between a control gate of a selected memory cell transistor M on a writing object page and the well by using a program operation. As a result, charge is injected into a charge storage layer of the memory cell transistor M (step S202). Incidentally, the potential is controlled to prevent charge from being injected into memory cell transistors M which have already passed the verify described below.

Then, the operation control circuit 7 reads data stored in the memory cell transistor M by verify operation (ordinary verify operation) after the program operation (step S203). As a result, verify data sensed by the sense amplifier circuit 3 is overwritten in the register 12a. For example, if the threshold voltage of the memory cell transistor M exceeds a verify level (writing is completed), data stored in the register 12a changes.

The operation control circuit 7 makes a determination whether the threshold voltage of the memory cell transistor M has exceeded the verify level based on data stored in the data register circuit 12 by the verify operation (step S204).

If the operation control circuit 7 determines at the step S204 that the threshold voltage of the memory cell transistor M has not exceeded the verify level in the verify operation, then the processing proceeds to step S205. At the step S205, the program voltage Vpgm is raised, and the processing returns to the step S202 to conduct the program operation again. Thereafter, the already described operation is conducted.

On the other hand, if the operation control circuit 7 determines at the step S204 that the threshold voltage of the memory cell transistor M has exceeded the verify level in the verify operation, then the operation control circuit 7 recognizes that the threshold voltage of the memory cell transistor M has passed the verify and the processing proceeds to write operation of data of high order (the second bit) shown in FIG. 14.

As shown in FIG. 14, the operation control circuit 7 first loads data. In other words, the operation control circuit 7 causes the same write data to be stored in the registers 12b and 12c in the data register circuit 12 (step S210). If write data loaded in the data register circuit 12 is data corresponding to the erase state (writing is not necessary), write operation is not conducted on the pertinent memory cell transistor M. The step S210 may be conducted at the same timing as that of the step S201.

Then, the operation control circuit 7 applies a first program voltage Vpgm1 between a control gate of each of selected memory cell transistors M on a writing object page and the well according to write data stored in the data register by using a first program operation. As a result, charge is injected into a charge storage layer of each memory cell transistor M according to the write data (step S211). Incidentally, the potential is controlled to prevent charge from being injected into memory cell transistors M which have already passed the verify described below.

Then, the operation control circuit 7 makes a determination whether to conduct first verify operation after first program operation on the memory cell transistor M to be brought into a first write state (step S212).

If the memory cell transistor M to be brought into the first write state has not passed the first verify, then the operation control circuit 7 proceeds to step S213 to conduct the first verify.

The operation control circuit 7 reads data stored in the memory cell transistor M to be brought into the first write state by conducting the first verify operation after the first program operation (step S213). As a result, verify data sensed by the sense amplifier circuit 3 is overwritten in the register 12b. For example, if the threshold voltage of the memory cell transistor M exceeds a verify level AV1 (FIG. 15) (i.e., if writing is completed), data stored in the register 12b changes.

On the other hand, if the memory cell transistor M to be brought into the first write state has already passed the first verify, then the operation control circuit 7 proceeds to step S214 without conducting the first verify.

Then, the operation control circuit 7 makes a determination whether to conduct second verify operation after the first program operation on the memory cell transistor M to be brought into a second write state (step S214).

If the memory cell transistor M to be brought into the second write state has not passed the second verify, then the operation control circuit 7 proceeds to step S215 to conduct the second verify.

The operation control circuit 7 reads data stored in the memory cell transistor M to be brought into the second write state by conducting the second verify operation after the first program operation (step S215). As a result, verify data sensed by the sense amplifier circuit 3 is overwritten in the register 12b. For example, if the threshold voltage of the memory cell transistor M exceeds a verify level BV1 (FIG. 15) (i.e., if writing is completed), data stored in the register 12b changes.

On the other hand, if the memory cell transistor M to be brought into the second write state has already passed the second verify, then the operation control circuit 7 proceeds to step S216 without conducting the second verify.

Then, the operation control circuit 7 makes a determination whether to conduct third verify operation after the first program operation on the memory cell transistor M to be brought into a third write state (step S216).

If the memory cell transistor M to be brought into the third write state has not passed the third verify, then the operation control circuit 7 proceeds to step S217 to conduct the third verify.

The operation control circuit 7 reads data stored in the memory cell transistor M to be brought into the third write state by conducting the third verify operation after the first program operation (step S217). As a result, verify data sensed by the sense amplifier circuit 3 is overwritten in the register 12b. For example, if the threshold voltage of the memory cell transistor M exceeds a verify level CV1 (FIG. 15) (i.e., if writing is completed), data stored in the register 12b changes.

On the other hand, if the memory cell transistor M to be brought into the third write state has already passed the third verify, then the operation control circuit 7 proceeds to step S218 without conducting the third verify.

The operation control circuit 7 makes a determination whether threshold voltages of respective memory cell transistors M exceed the corresponding first to third verify levels AV1 to CV1 (FIG. 15) (i.e., whether the threshold voltages of respective memory cell transistors M have passed the first to third verifies, based on data stored in the data register circuit 12 by the first to third verify operations (step S218).

If at the step S218 the operation control circuit 7 determines that the threshold voltage of some memory cell transistor M has not exceeded the corresponding one of the first to third verify levels AV1 to CV1 in the first to third verify operations, then the operation control circuit 7 proceeds to step S219. The operation control circuit 7 raises the first program voltage Vpgm1 at the step S219, and then returns to the step S211 to conduct the first program operation again. Thereafter, the already described operation is conducted.

On the other hand, if at the step S218 the operation control circuit 7 determines that the threshold voltages of respective memory cell transistors M have exceeded the first to third verify levels AV1 to CV1 in the first to third verify operations, then the operation control circuit 7 recognizes that respective memory cell transistors M have passed the first to third verifies and conducts first to third auxiliary verifies (with verify levels AV2 to CV2 (FIG. 15)) (steps S220 to S222).

The operation control circuit 7 makes a determination whether the threshold voltages of respective memory cell transistors M exceed verify levels AV2 to CV2 (FIG. 15) which are (for example, 0.1 V) respectively lower than the corresponding first to third verify levels AV1 to CV1 (step S223).

If at the step S223 the operation control circuit 7 determines that the threshold voltages of respective memory cell transistors M have not respectively exceeded the verify levels AV2 to CV2 (FIG. 15) in the first to third auxiliary verify operations, then the operation control circuit 7 proceeds to step S224.

At the step S224, a second program voltage Vpgm2 which is (for example, 2 V) lower than the first program voltage Vpgm1 is applied between control gates of respective memory cell transistors M connected in common to a word line (control gate) and the well by a second program operation (auxiliary program operation) after the first to third auxiliary verify operations. As a result, charge is injected into charge storage layers of respective memory cell transistors M.

As a result, the write operation on the respective memory cell transistors M on the pertinent page is finished.

In the same way as the first embodiment, the operation control circuit 7 controls, for example, the voltage applied to the control gate of the memory cell transistor M to cause the second program voltage Vpgm2 to become lower than the first program voltage Vpgm1 in the second program operation.

Or in the same way as the first embodiment, the operation control circuit 7 may control the voltage on the well (channel between diffusion layers of the memory cell transistor M) to cause the second program voltage Vpgm2 to become lower than the first program voltage Vpgm1 in the second program operation. In this case, for example, the operation control circuit 7 controls the voltage on the well by raising the potential on the bit line electrically connected to the diffusion layer of the memory cell transistor M.

On the other hand, if at the step S223 the operation control circuit 7 determines that the threshold voltages of respective memory cell transistors M have respectively exceeded the verify levels AV2 to CV2 (FIG. 15) in the first to third auxiliary verify operations, then the operation control circuit 7 recognizes that the threshold voltages of respective memory cell transistors M have passed all of the first to third auxiliary verifies and the second program operation is not conducted.

As a result, the write operation on the memory cell transistors M on the pertinent page is finished.

In the second embodiment, auxiliary verifies are conducted in the same way as the first embodiment, and in addition the auxiliary program operation is conducted. As a result, desired data can be written on the memory cell transistor M influenced by random telegraph noise (FIG. 15).

In the NAND flash memory 100 according to the second embodiment, therefore, it becomes possible to suppress the spread of the distribution width of the threshold voltage after the writing. Especially from the 30-nm generation (having the minimum line width of the memory cell transistor M of 30 nm or less) on which occurrence of great noise is expected, the spread of the distribution width of the threshold voltage after the writing can be suppressed more effectively.

In the same way as the first embodiment, it is possible to prevent the threshold voltage of the memory cell transistor M from becoming higher than needed (i.e., prevent the distribution width of the threshold voltage from expanding than needed) owing to the auxiliary program according to the auxiliary verify.

In the NAND flash memory according to the present embodiment, the spread of the distribution width of the threshold voltage of the memory cell can be suppressed as heretofore described.

### Third Embodiment

In the second embodiment, an example of the case where data stored in the memory cell transistor assumes a multiple value has been described.

In the present third embodiment, another example of the case where data stored in the memory cell transistor assumes a multiple value (especially four value (2 bits)) will be described.

In the same way as the second embodiment, a method described in the present third embodiment is executed by, for example, the NAND flash memory 100 shown in FIG. 5. Read operation of the NAND flash memory 100 is the same as that in the first embodiment.

The third embodiment is the same in the configuration of the data register circuit 12 as the second embodiment.

In the present third embodiment as well, the already described stepup write scheme is used. Write operation of data of low order (a first bit) of the NAND flash memory 100 according to the third embodiment is the same as that in the second embodiment (FIG. 13). Relations among the threshold voltage, the verify level and the number of cells of the memory cell transistors M in the NAND flash memory cell according to the third embodiment are similar to those in the second embodiment (FIG. 15).

Then, write operation of the NAND flash memory 100 having the above configuration according to the second embodiment will be described.

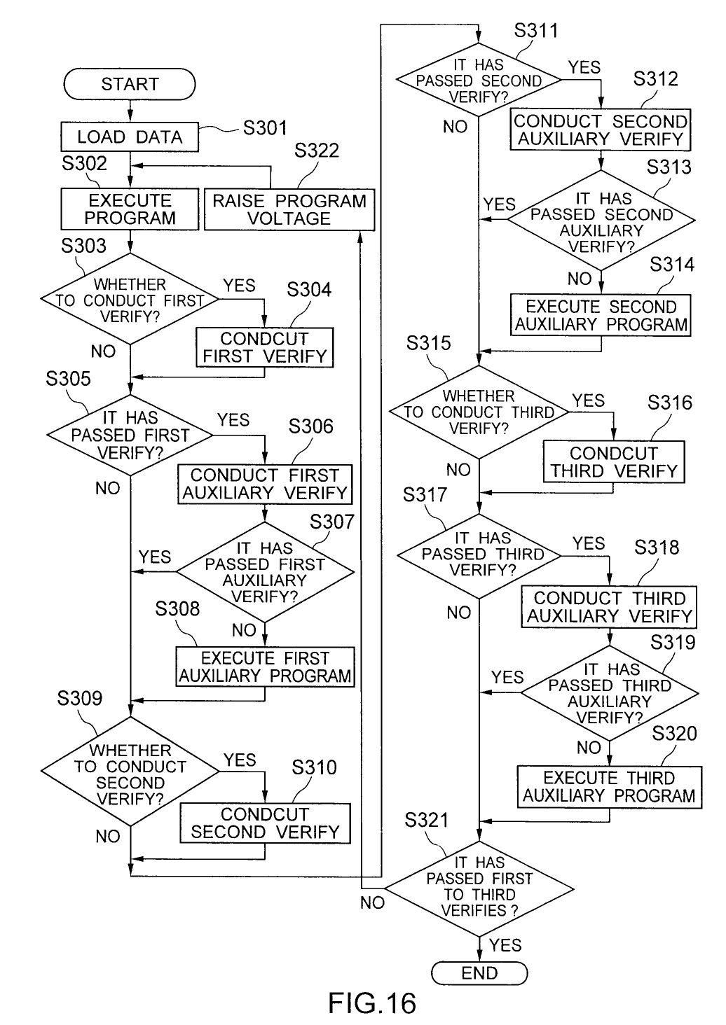

FIG. 16 is a flow chart showing another example of write operation of data of high order (a second bit) of the NAND flash memory 100 according to the second embodiment.

As shown in FIG. 16, the operation control circuit 7 loads data. In other words, the operation control circuit 7 causes the same write data to be stored in the registers 12b and 12c in the data register circuit 12 (step S301). If write data loaded in the data register circuit 12 is data corresponding to the erase state (writing is not necessary), write operation is not conducted on the pertinent memory cell transistor M. The step S301 may be conducted at the same timing as the step S201 already described.

Then, the operation control circuit 7 applies a first program voltage Vpgm1 between control gates of respective selected memory cell transistors M on a writing object page and the well according to write data stored in the data register circuit by using a first program operation. As a result, charge is injected into charge storage layers of respective memory cell transistors M according to the write data (step S302). Incidentally, the potential is controlled to prevent charge from being injected into memory cell transistors M which have already passed the verify described below.

Then, the operation control circuit 7 makes a determination whether to conduct first verify operation after first program operation on the memory cell transistor M to be brought into the first write state (step S303).

If the memory cell transistor M to be brought into the first write state has not passed the first verify, then the operation control circuit 7 proceeds to step S304 to conduct the first verify.

The operation control circuit 7 reads data stored in the memory cell transistor M to be brought into the first write state by conducting the first verify operation after the first program operation (step S304). As a result, verify data sensed by the sense amplifier circuit 3 is overwritten in the register 12b. For example, if the threshold voltage of the memory cell transistor M exceeds a verify level AV1 (FIG. 15) (i.e., if writing is completed), data stored in the register 12b changes.

On the other hand, if the memory cell transistor M to be brought into the first write state has already passed the first verify, then the operation control circuit 7 proceeds to step S305 without conducting the first verify.

The operation control circuit 7 makes a determination whether the threshold voltage of the memory cell transistor M has exceeded the corresponding first verify level AV1 (FIG. 15) (i.e., the threshold voltage of the memory cell transistor M has passed the first verify) based on data stored in the data register circuit 12 by conducting the first verify operation (step S305).

If at the step S305 the operation control circuit 7 determines that the threshold voltage of the memory cell transistor M has not exceeded the first verify level AV1 in the first verify operation, then the operation control circuit 7 proceeds to step S309.

On the other hand, if at the step S305 the operation control circuit 7 determines that the threshold voltage of the memory cell transistor M has exceeded the first verify level AV1 in the first verify operation, then the operation control circuit 7 recognizes that the threshold voltage of the memory cell transistor M has passed the first verify and conducts first auxiliary verify (with the verify level AV2 (FIG. 15)) (step S306).

The operation control circuit 7 makes a determination whether the threshold voltage of the memory cell transistor M has exceeded the verify level AV2 (FIG. 15) which is (for example, 0.1 V) lower than the corresponding first verify level AV1 (step S307).

If at the step S307 the operation control circuit 7 determines that the threshold voltage of the memory cell transistor M has not exceeded the verify level AV2 (FIG. 15) in the first auxiliary verify operation, then the operation control circuit 7 proceeds to step S308.

At step S308, the second program voltage Vpgm2 which is (for example, 2 V) lower than the first program voltage Vpgm1 is applied between the control gate of the memory cell transistor M and the well by conducting a second program operation (first auxiliary program operation) after the first auxiliary verify operation. As a result, charge is injected into the charge storage layer of the memory cell transistor M.

On the other hand, if at the step S307 the operation control circuit 7 determines that the threshold voltage of the memory cell transistor M has exceeded the verify level AV2 (FIG. 15) in the first auxiliary verify operation, then the operation control circuit 7 proceeds to step S309.

Then, the operation control circuit 7 makes a determination whether to conduct second verify operation after the first program operation on the memory cell transistor M to be brought into the second write state (step S309).

If the memory cell transistor M to be brought into the second write state has not passed the second verify, then the operation control circuit 7 proceeds to step S310 to conduct the second verify.

The operation control circuit 7 reads data stored in the memory cell transistor M to be brought into the second write state by conducting the second verify operation after the first program operation (step S310). As a result, verify data sensed by the sense amplifier circuit 3 is overwritten in the register 12b. For example, if the threshold voltage of the memory cell transistor M exceeds a verify level BV1 (FIG. 15) (i.e., if writing is completed), data stored in the register 12b changes.

On the other hand, if the memory cell transistor M to be brought into the second write state has already passed the second verify, then the operation control circuit 7 proceeds to step S311 without conducting the second verify.

The operation control circuit 7 makes a determination whether the threshold voltage of the memory cell transistor M has exceeded the corresponding second verify level BV1 (FIG. 15) (i.e., the threshold voltage of the memory cell transistor M has passed the second verify) based on data stored in the data register circuit 12 by conducting the second verify operation (step S311).

If at the step S311 the operation control circuit 7 determines that the threshold voltage of the memory cell transistor M has not exceeded the second verify level BV1 in the second verify operation, then the operation control circuit 7 proceeds to step S315.

On the other hand, if at the step S311 the operation control circuit 7 determines that the threshold voltage of the memory cell transistor M has exceeded the second verify level BV1 in the second verify operation, then the operation control circuit 7 recognizes that the threshold voltage of the memory cell transistor M has passed the second verify and conducts second auxiliary verify (with the verify level BV2 (FIG. 15)) (step S312).

The operation control circuit 7 makes a determination whether the threshold voltage of the memory cell transistor M has exceeded the verify level BV2 (FIG. 15) which is (for example, 0.1 V) lower than the corresponding second verify level BV1 (step S313).

If at the step S313 the operation control circuit 7 determines that the threshold voltage of the memory cell transistor M has not exceeded the verify level BV2 (FIG. 15) in the second auxiliary verify operation, then the operation control circuit 7 proceeds to step S314.

At step S314, the second program voltage Vpgm2 which is (for example, 2 V) lower than the first program voltage Vpgm1 is applied between the control gate of the memory cell transistor M and the well by conducting a second program operation (second auxiliary program operation) after the second auxiliary verify operation. As a result, charge is injected into the charge storage layer of the memory cell transistor M.

On the other hand, if at the step S313 the operation control circuit 7 determines that the threshold voltage of the memory cell transistor M has exceeded the verify level BV2 (FIG. 15) in the second auxiliary verify operation, then the operation control circuit 7 proceeds to step S315.

Then, the operation control circuit 7 makes a determination whether to conduct third verify operation after the first program operation on the memory cell transistor M to be brought into the third write state (step S315).

If the memory cell transistor M to be brought into the third write state has not passed the second verify, then the operation control circuit 7 proceeds to step S316 to conduct the third verify.

The operation control circuit 7 reads data stored in the memory cell transistor M to be brought into the third write state by conducting the third verify operation after the first program operation (step S316). As a result, verify data sensed by the sense amplifier circuit 3 is overwritten in the register 12b. For example, if the threshold voltage of the memory cell transistor M exceeds a verify level CV1 (FIG. 15) (i.e., if writing is completed), data stored in the register 12b changes.

On the other hand, if the memory cell transistor M to be brought into the third write state has already passed the third verify, then the operation control circuit 7 proceeds to step S317 without conducting the third verify.

The operation control circuit 7 makes a determination whether the threshold voltage of the memory cell transistor M has exceeded the corresponding third verify level CV1 (FIG. 15) (i.e., the threshold voltage of the memory cell transistor M has passed the third verify) based on data stored in the data register circuit 12 by conducting the third verify operation (step S317).

If at the step S317 the operation control circuit 7 determines that the threshold voltage of the memory cell transistor M has not exceeded the third verify level CV1 in the third verify operation, then the operation control circuit 7 proceeds to step S321.

On the other hand, if at the step S317 the operation control circuit 7 determines that the threshold voltage of the memory cell transistor M has exceeded the third verify level CV1 in the third verify operation, then the operation control circuit 7 recognizes that the threshold voltage of the memory cell transistor M has passed the third verify and conducts third auxiliary verify (with the verify level CV2 (FIG. 15)) (step S318).

The operation control circuit 7 makes a determination whether the threshold voltage of the memory cell transistor M has exceeded the verify level CV2 (FIG. 15) which is (for example, 0.1 V) lower than the corresponding third verify level CV1 (step S319).

If at the step S319 the operation control circuit 7 determines that the threshold voltage of the memory cell transistor M has not exceeded the verify level CV2 (FIG. 15) in the third auxiliary verify operation, then the operation control circuit 7 proceeds to step S320.

At step S320, the second program voltage Vpgm2 which is (for example, 2 V) lower than the first program voltage Vpgm1 is applied between the control gate of the memory cell transistor M and the well by conducting a second program operation (third auxiliary program operation) after the third auxiliary verify operation. As a result, charge is injected into the charge storage layer of the memory cell transistor M.

On the other hand, if at the step S319 the operation control circuit 7 determines that the threshold voltage of the memory cell transistor M has exceeded the verify level CV2 (FIG. 15) in the third auxiliary verify operation, then the operation control circuit 7 proceeds to step S321.

The operation control circuit 7 makes a determination whether threshold voltages of respective memory cell transistors M exceed the corresponding first to third verify levels AV1 to CV1 (FIG. 15) (i.e., whether the threshold voltages of respective memory cell transistors M have passed the first to third verifies, based on data stored in the data register circuit 12 by the first to third verify operations (step S321).

If at the step S321 the operation control circuit 7 determines that the threshold voltage of some memory cell transistor M has not exceeded the corresponding one of the first to third verify levels AV1 to CV1 in the first to third verify operations, then the operation control circuit 7 proceeds to step S322. The operation control circuit 7 raises the first program voltage Vpgm1 at the step S322, and then returns to the step S211 to conduct the first program operation again. Thereafter, the already described operation is conducted.

On the other hand, if at the step S321 the operation control circuit 7 determines that the threshold voltages of respective memory cell transistors M have exceeded the first to third verify levels AV1 to CV1 (FIG. 15) in the first to third auxiliary verify operations, then the operation control circuit 7 finishes the write operation on the memory cell transistors M on the pertinent page.

In the third embodiment, auxiliary verifies are conducted in the same way as the first embodiment, and in addition the auxiliary program operation is conducted. As a result, desired data can be written on the memory cell transistor M influenced by random telegraph noise (FIG. 15).

In the NAND flash memory 100 according to the third embodiment, therefore, it becomes possible to suppress the spread of the distribution width of the threshold voltage after the writing. Especially from the 30-nm generation (having the minimum line width of the memory cell transistor M of 30 nm or less) on which occurrence of great noise is expected, the spread of the distribution width of the threshold voltage after the writing can be suppressed more effectively.

In the same way as the first embodiment, it is possible to prevent the threshold voltage of the memory cell transistor M from becoming higher than needed (i.e., prevent the distribution width of the threshold voltage from expanding than needed) owing to the auxiliary program according to the auxiliary verify.

In the NAND flash memory according to the present embodiment, the spread of the distribution width of the threshold voltage of the memory cell can be suppressed as heretofore described.

In the NAND flash memory of floating gate type, noise is caused typically by electron traps in the tunnel oxide film. Therefore, the embodiments have been described by using electron traps. However, the kind of traps is not restricted to electron traps.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A NAND flash memory comprising:
a memory cell transistor, the memory cell transistor including a charge storage layer formed over a well of a semiconductor substrate surface via a first insulation film, and a control gate provided over the charge storage layer via a second insulation film; and
a control circuit which controls operation of the memory cell transistor by controlling a voltage applied to the control gate and a voltage applied to the well,
the control circuit making a determination whether a threshold voltage of the memory cell transistor exceeds a first verify level in a first verify operation after the first program operation,
upon determining the threshold voltage of the memory cell transistor to exceed the first verify level in the first verify operation, the control circuit making a determination whether the threshold voltage of the memory cell transistor exceeds a second verify level which is lower than the first verify level in a second verify operation after the first verify operation, and
upon determining the threshold voltage of the memory cell transistor not to exceed the second verify level in the second verify operation, the control circuit applying a second program voltage which is lower than the first program voltage between the control gate and the well in a second program operation after the second verify operation.

2. The NAND flash memory according to claim 1, wherein in the second program operation, the control circuit controls the voltage applied to the control gate to cause the second program voltage to become lower than the first program voltage.

3. The NAND flash memory according to claim 1, wherein in the second program operation, the control circuit controls the voltage applied to the well to cause the second program voltage to become lower than the first program voltage.

4. The NAND flash memory according to claim 3, wherein the control circuit controls the voltage applied to the well by raising a potential on a bit line connected electrically to a diffusion layer of the memory cell transistor.

5. The NAND flash memory according to claim 1, wherein if the control circuit determines that the threshold voltage of the memory cell transistor has not exceeded the first verify level in the first verify operation, then the control circuit raises the first program voltage is raised and conducts the first program operation again.

6. The NAND flash memory according to claim 2, wherein if the control circuit determines that the threshold voltage of the memory cell transistor has not exceeded the first verify level in the first verify operation, then the control circuit raises the first program voltage is raised and conducts the first program operation again.

7. The NAND flash memory according to claim 3, wherein if the control circuit determines that the threshold voltage of the memory cell transistor has not exceeded the first verify level in the first verify operation, then the control circuit raises the first program voltage is raised and conducts the first program operation again.

8. The NAND flash memory according to claim 4, wherein if the control circuit determines that the threshold voltage of the memory cell transistor has not exceeded the first verify level in the first verify operation, then the control circuit raises the first program voltage is raised and conducts the first program operation again.

9. The NAND flash memory according to claim 1, wherein if the control circuit determines that the threshold voltage of the memory cell transistor has exceeded the second verify level in the second verify operation, then the control circuit does not conduct the second program operation.

10. The NAND flash memory according to claim 2, wherein if the control circuit determines that the threshold voltage of the memory cell transistor has exceeded the second verify level in the second verify operation, then the control circuit does not conduct the second program operation.

11. The NAND flash memory according to claim 3, wherein if the control circuit determines that the threshold voltage of the memory cell transistor has exceeded the second verify level in the second verify operation, then the control circuit does not conduct the second program operation.

12. The NAND flash memory according to claim 4, wherein if the control circuit determines that the threshold voltage of the memory cell transistor has exceeded the second verify level in the second verify operation, then the control circuit does not conduct the second program operation.

13. The NAND flash memory according to claim 5, wherein if the control circuit determines that the threshold voltage of the memory cell transistor has exceeded the second verify level in the second verify operation, then the control circuit does not conduct the second program operation.

14. The NAND flash memory according to claim 1, wherein a minimum line width of the memory cell transistor is 30 nm or less.

15. The NAND flash memory according to claim 2, wherein a minimum line width of the memory cell transistor is 30 nm or less.

16. The NAND flash memory according to claim 3, wherein a minimum line width of the memory cell transistor is 30 nm or less.

17. The NAND flash memory according to claim 4, wherein a minimum line width of the memory cell transistor is 30 nm or less.

18. The NAND flash memory according to claim 5, wherein a minimum line width of the memory cell transistor is 30 nm or less.

19. The NAND flash memory according to claim 9, wherein a minimum line width of the memory cell transistor is 30 nm or less.

20. A NAND flash memory comprising:
a memory cell transistor, the memory cell transistor including a charge storage layer formed over a well of a semiconductor substrate surface via a first insulation film and insulated from surroundings, and a control gate provided over the charge storage layer via a second insulation film, the memory cell transistor storing information according to a threshold voltage which depends on a charge quantity retained by the charge storage layer; and
a control circuit which controls operation of the memory cell transistor by controlling a voltage applied to the control gate and a voltage applied to the well,
the control circuit injecting charges into the charge storage layer by applying a first program voltage between the control gate and the well in a first program operation,
the control circuit making a determination whether the threshold voltage of the memory cell transistor exceeds a first verify level in a first verify operation after the first program operation,
upon determining the threshold voltage of the memory cell transistor to exceed the first verify level in the first verify operation, the control circuit making a determination whether the threshold voltage of the memory cell transistor exceeds a second verify level which is lower than the first verify level in a second verify operation after the first verify operation, and
upon determining the threshold voltage of the memory cell transistor not to exceed the second verify level in the second verify operation, the control circuit injecting charges into the charge storage layer by applying a second program voltage which is lower than the first program voltage between the control gate and the well in a second program operation after the second verify operation.
